(19) United States
(12) Patent Application Publication
(10) Pub. No.: US 2010/0127407 A1
(43) Pub. Date: May 27, 2010

(54) Two-sided substrateless multichip module and method of manufacturing same

(76) Inventors: John LeBlanc, North Andover, MA (US); Brad Gaynor, Newton, MA (US); David Hagerstrom, Amherst, NH (US); Caroline Bjune, Andover, MA (US)

Correspondence Address: Iandiorio & Teska, 260 Bear Hill Road, Waltham, MA, 02451-1018, US

(21) Appl. No.: 12/313,900

(22) Filed: Nov. 25, 2008

(51) Int. Cl. H01L 23/52; H01L 23/48; H01L 21/00; H01L 23/482; H01L 23/495; H01L 23/522; H01L 21/70

(52) U.S. Cl. 257/777; 257/786; 438/109; 438/118; 257/E25.029; 257/E23.011; 257/E23.012; 257/E23.052; 257/E23.142; 257/E21.532

(57) ABSTRACT

A two-sided substrateless multichip module including at least one die layer having at least one die. At least one bottomside interconnect layer is coupled to a bottom surface of the at least one die. At least one topside interconnect layer is coupled to a top surface of the at least one die. One or more embedded electrical connections is configured to provide an electrical interconnection between the at least one bottomside interconnect layer and the at least one die and/or the at least bottomside interconnect layer and the at least one topside interconnect layer and/or the at least one topside interconnect layer and the at least one die, wherein the at least one bottomside interconnect layer includes one or more electrical contacts on a bottom surface of the multichip module and the at least topside interconnect layer includes one or more electrical contacts on a top surface of the multichip module.

### FIELD OF THE INVENTION

This invention relates to a two-sided substrateless multichip module (MCM) and method of manufacturing same.

### BACKGROUND OF THE INVENTION

A typical conventional MCM is a chip package that includes multiple chips, or die, mounted in close proximity to each other on a rigid substrate. MCMs are often classified by the type of substrate. For example, MCM-C typically includes a ceramic substrate with wire bonding connecting the chips. MCM-D typically includes a dielectric layer over a rigid ceramic, glass or metal substrate and a thin film of interconnects created on the dielectric layer. However, the bottom surface of the rigid substrate of conventional MCMs cannot be processed to include additional die, interconnects, or any other various electronic components. The result is the packaging density of a typical conventional “one-sided” MCM is significantly reduced. Moreover, the rigid substrate of a one-sided conventional MCM prevents it from being flexible.

One prior attempt to increase the packaging density of conventional MCMs includes gluing two MCM-D type modules together. Using this technique, electrical contacts are often made around the side or through a hole in the module. However, gluing two modules together requires producing MCMs which increases cost. Leaving room for the interconnect requires either a hole in the MCM or an additional area around the side of the MCM which reduces packaging density. Additionally, the external interconnect lack support for integrated electrical connections between the two MCM which reduces signal integrity.

### BRIEF SUMMARY OF THE INVENTION

It is therefore an object of this invention to provide a two-sided substrateless multichip module and method of manufacturing same.

It is a further object of this invention to provide such a two-sided substrateless multichip module and method which increases packaging density.

It is a further object of this invention to provide such a two-sided substrateless multichip module and method which can be processed on both the top surface and the bottom surface of the multichip module.

It is a further object of this invention to provide such a two-sided substrateless multichip module and method in which die and/or electronic components and/or intereconnects can be attached to both the top surface and the bottom surface of the multichip module.

It is a further object of this invention to provide such a two-sided substrateless multichip module and method which can stack multiple die layers within the multichip module.

It is a further object of this invention to provide such a two-sided substrateless multichip module and method which is compatible with Surface Mount Technology (SMT) components.

It is a further object of this invention to provide such a two-sided substrateless multichip module which may be flexible.

It is a further object of this invention to provide such a two-sided substrateless multichip module and method which reduces costs.

It is a further object of this invention to provide such a two-sided substrateless multichip module and method which improves electrical performance.

It is a further object of this invention to provide such a two-sided substrateless multichip module and method which reduces thermal stress on the die.

The subject invention, however, in other embodiments, need not achieve all these objectives and the claims hereof should not be limited to structures or methods capable of achieving these objectives.

This invention features a two-sided substrateless multichip module including at least one die layer having at least one die, at least one bottomside interconnect layer coupled to a bottom surface of the at least one die at least one topside interconnect layer coupled to a top surface of the at least one die, one or more embedded electrical connections configured to provide an electrical interconnection between the at least one bottomside interconnect layer and the at least one die and/or the at least bottomside interconnect layer and the at least one topside interconnect layer and/or the at least one topside interconnect layer and the at least one die, and wherein the at least one bottomside interconnect layer includes one or more electrical contacts on a bottom surface of the multichip module and the at least topside interconnect layer includes one or more electrical contacts on a top surface of the multichip module.

In one embodiment, the at least one bottomside interconnect layer may include a flex circuit. The one or more of the electrical contacts on the bottom surface and/or the top surface may have a predetermined pattern. The predetermined pattern may be configured for attachment of one or more surface mount technology components. The one or more electrical contacts may each provide an electrical connection to one or more of: solder balls and/or surface mount parts and/or external interconnect layers, flip chip die, and wire bonds. The at least one bottomside interconnect layer and the at least one topside interconnect layer may each include a dielectric layer and one or more of metal traces, electrical contacts and vias. The dielectric layer may include an adhesive. The dielectric layer may be comprised of polyimide. The flex circuit may be configured for a predetermined die. The at least one bottomside interconnect layer may be configured as a heat sink. The at least one topside interconnect layer may be configured as a heat sink. The one or more electrical connections may include one or more vias. The at least one die layer may include a dielectric spacer element. The dielectric spacer may be comprised of polyimide. The two-sided substrateless multichip module may include a plurality of bottomside interconnect layers. The two-sided substrateless multichip module may include a plurality of topside interconnect layers. The at least one die layer may include a plurality of dies. The two-sided substrateless multichip module may include a plurality of stacked die layers each sandwiched between at least one topside interconnect layer and at least one bottomside interconnect layer and having one or more electrical interconnections between the plurality of stacked die layers and/or between the at least one bottomside interconnect layer and the at least one die and/or the at least one topside interconnect layer and the bottomside interconnect layer and/or the at least one topside interconnect layer and the at least one die.

This invention also features a two-sided substrateless single chip module including at least one die layer having at least one die, at least one bottomside interconnect layer coupled to a bottom surface of the at least one die, at least one topside interconnect layer coupled to a top surface of the at least one die, one or more embedded electrical connections configured to provide an electrical interconnection between the at least one bottomside interconnect layer and the at least one die and/or the at least bottomside interconnect layer and the at least one topside interconnect layer and/or the at least one topside interconnect layer and the at least one die, and wherein the at least one bottomside interconnect layer includes one or more electrical contacts on a bottom surface of the multichip module and the at least topside interconnect layer includes one or more electrical contacts on a top surface of the multichip module.

This invention further features a method of fabricating a two-sided substrateless multichip module, the method including providing at least one bottomside interconnect layer, forming a die layer having at least one die on the at least one bottomside interconnect layer, forming at least one topside interconnect layer on the die layer, and providing one or more electrical interconnections between the at least one bottomside interconnect layer and the at least one die and/or the at least one topside interconnect layer and the at least one bottomside interconnect layer and/or the at least one topside interconnect layer and the at least one die.

In one embodiment, the at least one bottomside interconnect layer may include a flex circuit, providing one or more electrical interconnections may include forming one or more vias between the at least one bottomside interconnect layer and the at least one die and/or the at least one topside interconnect layer and the at least one bottomside interconnect layer and/or the at least one topside interconnect layer in the at least one die. The method may include the step of providing at least one spacer element to the die layer. The method may include the step of providing one or more electrical contacts on a bottom surface of the two-sided substrateless multichip module. The method may include the step of providing one or more electrical contacts on a top surface layer of the two-sided substrateless multichip module. The one or more electrical contacts may form in a predetermined pattern. The predetermined pattern may be configured for attachment of one or more surface mount technology components. The predetermined pattern may be configured for attachment of one or more of: solder balls and/or surface mount parts and/or external interconnect layers.

This invention also features a method of fabricating a two-sided substrateless single chip module, the method including providing at least one bottomside interconnect layer, forming a die layer having at least one die on the at least one bottomside interconnect layer, forming at least one topside interconnect layer on the die layer, and providing one or more electrical interconnections between the at least one bottomside interconnect layer and the at least one die and/or the at least one topside interconnect layer and the at least one bottomside interconnect layer and/or the at least one topside interconnect layer and the at least one die.

This invention further features a method for fabricating one or more two-sided substrateless multichip modules, the method including providing a frame having at least one opening therein, bonding a dielectric film to one surface of the frame, forming a die layer having at least one die in an area defined by the at least one opening, bonding another dielectric film to the other surface of the frame, forming at least one topside interconnect layer from the dielectric film on the one surface of the frame, forming at least one bottomside interconnect layer from the dielectric film on the other surface of the frame, and forming one or more electrical interconnections between the at least one bottomside interconnect layer and the at least one die and/or the at least one bottomside interconnect layer and the at least one topside interconnect layer and/or the at least one topside interconnect layer and the at least one die.

In one embodiment, the method may include the step of forming one or more die layers having at least one die therein on the at least one topside interconnect layer and/or the at least one bottomside interconnect layer. The dielectric film may include a flex circuit. The frame may be thermally matched to the dielectric. The frame may be thermally matched to the at least one die. The frame may be made of a material chosen from the group consisting of: stainless steel, brass, silicone, and a rigid polymer. The one or more die layers may each be sandwiched between at least one topside interconnect layer and at least one bottomside interconnect layer. The method may include a plurality of die in the die layer each placed in the opening such that the active surface of each of the die is co-planar.

This invention also features a method for fabricating one or more two-sided substrateless single chip modules, the method including providing a frame having at least one opening therein, bonding a dielectric film to one surface of the frame, forming a die layer having at least one die in an area defined by the at least one opening, bonding another dielectric film to the other surface of the frame, forming at least one topside interconnect layer from the dielectric film on the one surface of the frame, forming at least one bottomside interconnect layer from the dielectric film on the other surface of the frame, and forming one or more electrical interconnections between the at least one bottomside interconnect layer and the at least one die and/or the at least one bottomside interconnect layer and the at least one topside interconnect layer and/or the at least one topside interconnect layer and the at least one die.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic side-view showing one embodiment of the primary components of the two-sided substrateless multichip module of this invention;

FIG. 2 is a schematic side-view of another embodiment the two-sided substrateless multichip module of this invention having a plurality of topside interconnect layers and a plurality of bottomside interconnect layers;

FIG. 3 is a schematic side-view showing one example the two-sided substrateless multichip module shown in FIG. 2 having SMT components mounted on a top surface of the module and a plurality of solder balls mounted on a bottom surface of the module;

FIG. 4 is a schematic side-view of one embodiment of the circuit shown in FIGS. 1-3 configured as a heat sink;

FIG. 5 is a schematic side-view yet another embodiment example the two-sided substrateless MCM of this invention having a plurality of die layers therein;

FIG. 6 is a schematic block diagram showing one embodiment of the primary steps associated with the method of fabricating the two-sided substrateless multichip module of this invention;

FIG. 7A-7C are schematic side-views showing the primary components associated with the method of fabricating the two-sided substrateless multichip shown in FIG. 5;

FIG. 8 is a schematic block diagram showing another embodiment of the primary steps associated with the method of fabricating the two-sided substrateless multichip module of this invention;

FIGS. 9A-9E is a schematic side-views showing the primary components associated with the method of fabricating a two-sided substrateless multichip shown in FIG. 8; and

FIG. 10 is a schematic top-view showing another example of the frame shown in FIGS. 9A and 9B bonded to a dielectric film and a die in the opening of the frame.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

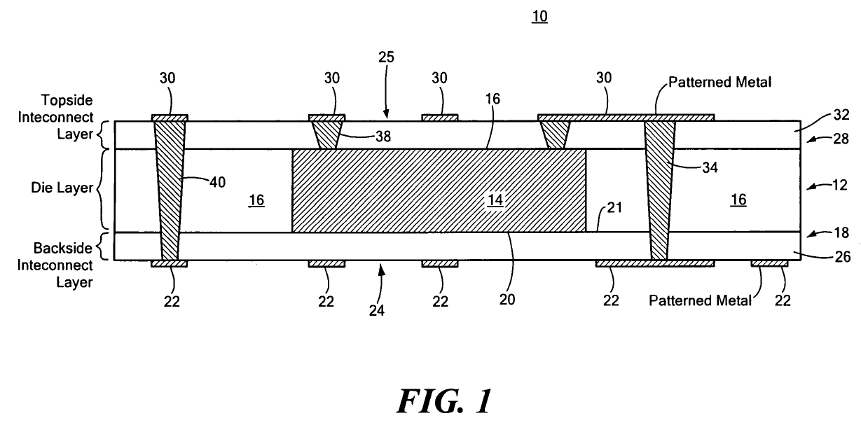

There is shown in FIG. 1, one embodiment of two-sided substrateless multichip module 10 of this invention. Module 10 includes at least one die layer 12 having at least die 14. Die 14, e.g. a chip, integrated circuit chip (IC), microcircuit, microchip, silicon chip, or similar type device, includes active top surface 16. In one design, die layer 12 includes spacer element 16 disposed on both sides of die 14, e.g., a dielectric material, such as polyimide or similar type material. Module 10 also includes at least one bottomside interconnect layer 18 coupled to bottom surface 20 of die 14. In one example, bottom surface 20 of die 14 is glued to top surface 21 of interconnect layer 18 with an adhesive, e.g., a glue such as butylphenolic adhesive or similar type adhesive. In one preferred embodiment, bottomside interconnect layer 18 may be a flex circuit available from All Flex (Northfield, Mass.). As known by those skilled in the art, a flex circuit may be custom manufactured for various predetermined die, electronic components, SMT components, surface mount parts, interconnect, and the like. The flex circuit also provides module 10 with flexibility as needed. Bottomside interconnect layer 18 preferable includes electrical contacts 22, e.g. metal pads and/or patterned metal (metal traces) on bottom surface 24 of module 10. Bottomside interconnect layer 18 typically includes dielectric substrate 26, e.g. polyimide, or similar type material. Bottomside interconnect layer 18 may be purchased as a flex circuit as discussed above, or may be processed using lamination, photolithography, and the like, as known by those skilled in the art.

Two-sided substrateless multichip module 10 further includes at least one topside interconnect layer 28 coupled to the top active surface 16 of die 14 and typically to spacer element 16. Topside interconnect layer 28 similarly includes electrical contacts 30 which may include electrical pads and/or patterned metal (metal traces). Topside interconnect layer 18 also preferably includes dielectric substrate 32, e.g. polyimide, or similar type material, as discussed above. Topside interconnect layer 28 with electrical contacts 30 are preferably processed over die layer 12 using lamination, photolithography, and the like.

Two-sided substrateless multichip module 10 further includes one or more embedded electrical connections, e.g., vias 34, 36, 38, and 40, configured to provide an electrical interconnection between bottomside interconnect layer 18 and top active surface 16 of die 14 and/or an electrical interconnection between bottomside interconnect layer 18 and topside interconnect layer 28 and/or an electrical interconnection between topside interconnect layer 28 and top active surface 16 of die 14. For example, via 34 provides an electrical interconnection between bottomside interconnect layer 18 and topside interconnect layer 28. Vias 36 and 38 provide an electrical interconnection between topside interconnect layer 28 and top active surface 16 of die 14. The combination of vias 34 and via 36 provides an electrical interconnection between bottomside interconnect layer 18 and top active surface 16 of die 14. Via 40 similarly provides an electrical connection between bottomside interconnect layer 18 and topside interconnect layer 28. Vias 34-40 are drilled, metal coated, and processed using methods known to those skilled in the art.

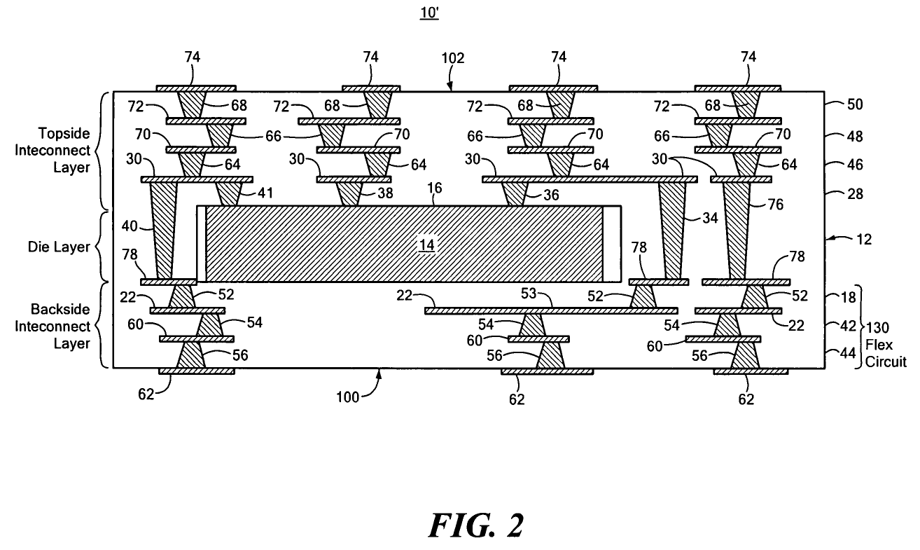

In one embodiment, multichip module 10′, FIG. 2, where like parts have been given like numbers, may include a plurality of bottomside interconnect layers, e.g., bottomside interconnect layers 18, 42, and 44. In this example, each of bottomside interconnect layers 18, 42, 44 may include one or more electrical connections, e.g., vias 52, 54, and 56, respectively, which electrically interconnect layers 18, 42 and 44 to each other. Bottomside interconnect layer 18 preferably includes electrical contacts 22 and 78, e.g. metal pads and/or patterned metal (metal traces), similar as discussed above. In this exemplary design, bottomside interconnect layer 42 includes electrical contacts 60 (e.g. metal pads and/or patterned metal (metal traces)) and bottomside interconnect layer 44 includes electrical contacts 62 (e.g. metal pads and/or patterned metal (metal traces)). In this embodiment, electrical contacts 62 are located on bottom surface 100 of module 10′. Each of bottomside interconnect layers 18, 42, 44 similarly include a dielectric substrate, e.g., polyimide, similar as discussed above. Bottomside interconnect layers 18, 42, and 44 may be configured as flex circuit 130, which may be purchased or manufactured, as discussed above. Bottomside interconnect layers 18, 42, and 44 may also be processed using lamination, photolithography, and the like, as known by those skilled in the art. Module 10′, FIG. 2, may also include a plurality of topside interconnect layers, e.g., topside interconnect layers 28, 46, 48, and 50. Each of topside interconnect layers 28, 48, and 50 may include one or more electrical connections, e.g., vias 36, 38, and 41 in topside interconnect layer 28, and vias 64, 66, and 68 in topside interconnect layers 46, 48, and 50, respectively, which electrically interconnect layers 28, 46, 48, and 50 to each other and to top active surface 16 of die 14. Topside interconnect layers 28, 46, 48, and 50 typically include electrical contacts 30, 70, 72, and 74, respectively of similar design as contacts 22, 60 and 62 discussed above. In this example, electrical contacts 74 are located on top surface 102 of module 10′. Each of topside interconnect layer 28, 46-50 similarly include a dielectric substrate, e.g., polyimide, or similar type material as discussed above with reference to FIG. 1. Topside interconnect layer 28, 46-50 are typically built using lamination, photolithography, and the like, as discussed above.

Module 10′ also includes electrical connections, e.g., vias 34, 76, and 40 which provide an electrical interconnection between bottomside interconnect layer 18 and topside interconnect layer 28. The result is each of bottomside interconnect layers 18, 42, 44 are electrically interconnected with each other and to each of topside interconnect layers 28, 46, 48, and 50. Similarly, each of bottomside interconnect layers 18, 42, and 44 and each of topside interconnect layers 28, 46, 48, and 50 are also electrically interconnected to top active surface 16 of die 14. Electrical contacts 62 on bottom surface 100 of MCM 10′ provide an electrical connection to top active surface 16 of die 14 and electrical contacts 74 on top surface 102 provide an electrical connection to top active surface 16 of die 14. Thus, two-sided substrateless MCM 10′ of this invention provides for attachment of electronic components, SMT components, solder balls, and the like, to both top surface 102 and bottom surface 100 of MCM 10′ to effectively increase the packaging density of electronic components of module 10′, as discussed in further detail below.

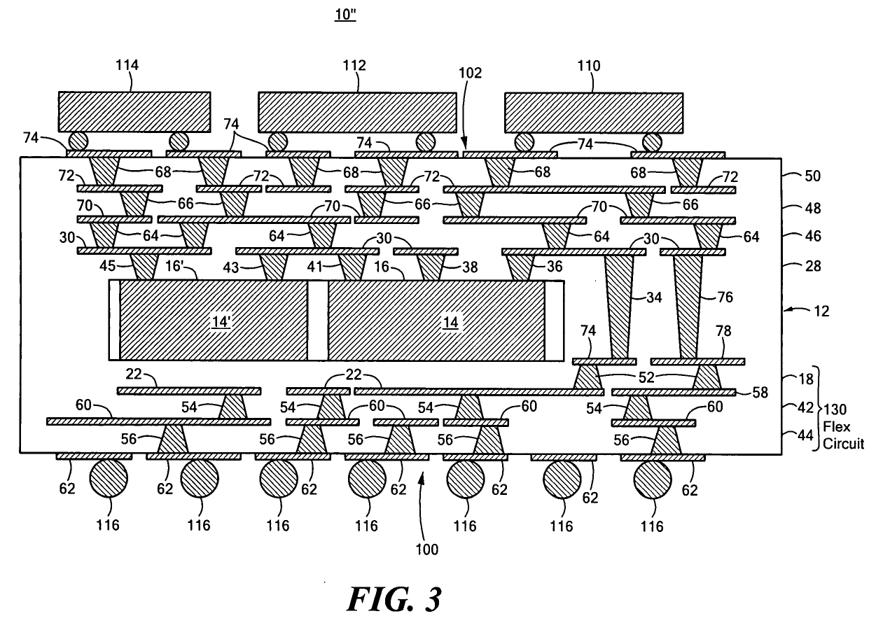

In another embodiment, two-side substrateless multichip module 10″, FIG. 3, where like parts have been given like numbers, includes a plurality of bottomside interconnect layers 18, 42, and 44 which have a slightly different configuration of vias 52, 54, 56 and electrical contacts 22, 60 and 62, respectively. Module 10″ also includes a plurality of topside interconnect layers 28, 46, 48, and 50. In this embodiment, topside interconnect layer 28 has a slightly different configuration of vias 36, 38, 41 and electrical contacts 30 and now includes vias 43 and 45. Topside interconnect layers 46, 48 and 50 also have a different configuration of vias 64, 66, and 68, respectively, and electrical contacts 70, 72, and 74, respectively. In this example, die layer 12 includes two die, die 14 and 14′ having active top surfaces 16, 16′, respectively.

Electrical contacts 74, FIGS. 2 and 3, on top surface 102 may have a predetermined pattern and configuration for attachment of SMT components, e.g. SMT components 110, 112, and 114, FIG. 3. Electrical contacts 62 on bottom surface 100 may also have a predetermined pattern and configuration for attachment of solder balls 116, e.g. for a ball grid array (BGA), or any other various electronic components, surface mounts parts, external interconnect layers, conductive epoxy, and the like, as known by those skilled in the art.

Although as shown in FIG. 3, electrical contacts 74 on top surface 102 of module 10″ are configured for attachment of SMT components 110-114 and electrical contacts 62 on bottom surface 100 are configured for attachment of solder balls 1 16, this is not a necessary limitation of this invention, as SMT components may be coupled to electrical contacts 62 on bottom surface 100 of module 10″ and solder balls, various electronic components, surface mounts parts, external interconnect layers, and/or conductive epoxy, and the like, may be coupled to electrical contacts 74 on top surface 102 of module 10″, or SMT components, and/or solder balls and/or various electronic components, surface mounts parts, external interconnect layers, conductive epoxy, and the like, may both be coupled to both electrical contacts 62 and 74, or any combination thereof. Electrical contacts 62 and 74 do not necessarily need to have any type of predetermined pattern.

The result is two-sided substrateless multichip module 10, FIGS. 1-3 of this invention provides for attachment and electrical interconnection of various electronic components, SMT components, solder balls, surface mounts parts, external interconnect layers, conductive epoxy, and the like, to both top surface 102 and bottom surface 100 of multichip module 10. Such a design significantly increases the packaging density of electronic components which can be coupled to two-side substrateless multichip module 10. In one example, the packaging density, measured in circuit volume divided by functional electronics, was increased to 30 to 1. In contrast, a typical one-sided conventional multichip module as discussed in the Background section has a packaging density of about 100 to 1. Moreover, module 10 eliminates the need to make electrical contacts around the side, or through a hole, in the module as required when two MCM-D type modules are glued together, which reduces costs associated with module 10. Module 10 also eliminates the need for external interconnect which improves signal integrity. Moreover, when the bottomside interconnect layers are configured as a flex circuit, module 10 can be flexible as needed.

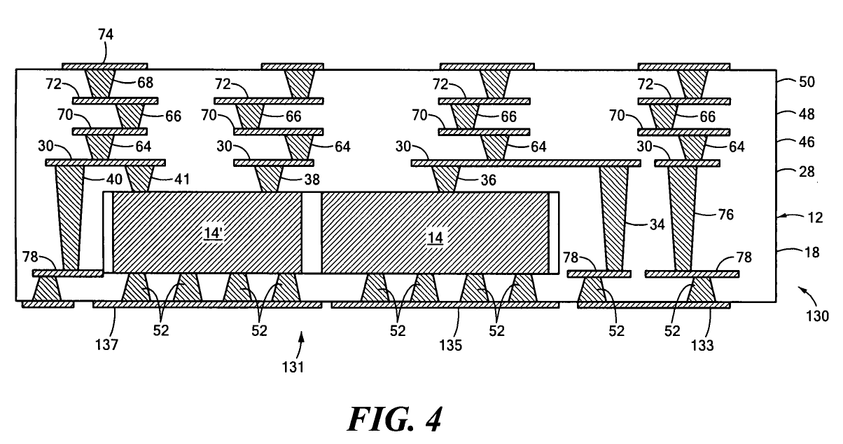

In one embodiment, flex circuit 130, FIG. 4, where like parts have been given like numbers, may be configured as a heat sink, e.g., heat sink 131. In this design, heat sink 131 includes bottomside interconnect layer 18 and metal contacts 22 coupled to vias 52.

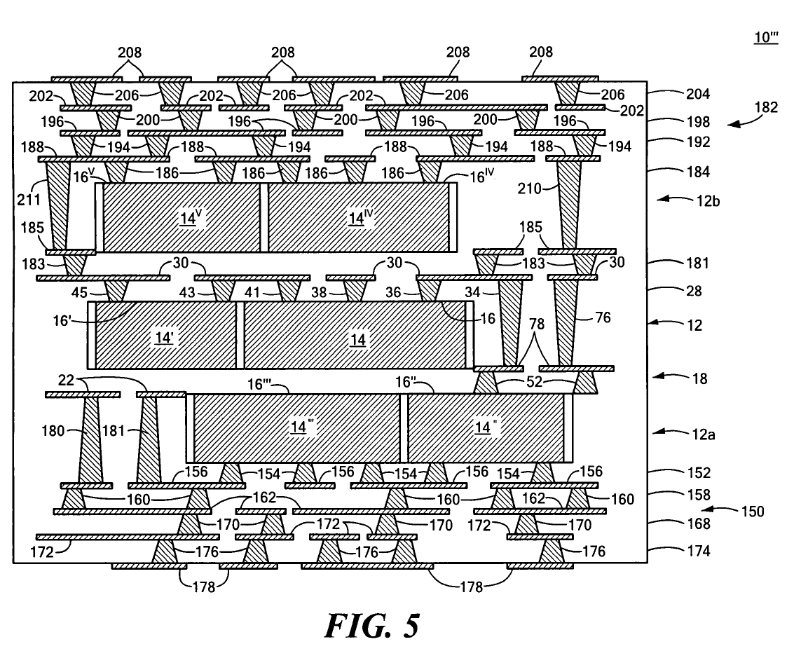

In another embodiment of this invention, two-side substrateless multichip module 10′″, FIG. 5, where like parts have been given like numbers, may include a plurality of stacked die layers within MCM 10′″ which are each disposed between one or more topside interconnect layers and one or more bottomside interconnect layers. For example, multichip module 10′″ may include die layers 12, 12a, 12b. In this design, die layer 12 with die 14, 14′ is disposed between bottomside interconnect layer 18 having vias 52 and electrical contacts 22 and topside layer 28 with vias 36, 38, 41, 43, and 45 and electrical contacts 30, similar as discussed above in reference to FIGS. 2 and 3. Die layer 12a with die 14″, 14′″ is disposed between bottomside interconnect layer 18 (which now acts the topside layer) and bottomside interconnect layer 150 which, in this example, includes bottomside interconnect layers 152, 158, 168, and 174. Bottomside interconnect layer 152 includes vias 154 and electrical contacts 156, bottomside interconnect layer 158 includes vias 160 and electrical contacts 162, bottomside interconnect layer 168 includes vias 170 and electrical contacts 172, and bottomside interconnect layer 174 includes vias 176 and electrical contacts 178. Die layer 12b having die 14^{iv}, 14^{v} is disposed between bottomside interconnect layer 181 with vias 183 and electrical contacts 185 and topside interconnect layer 182. In this example, topside interconnect layer 182 includes topside interconnect layer 184 with vias 186 and electrical contacts, topside interconnect layer 192 with vias 194 and electrical contacts 196, topside interconnect layer 198 with vias 200 and electrical contacts 202, and topside interconnect layer 204 with vias 206 and electrical contacts 208.

Module 10′″ also includes embedded electrical connections, e.g., vias 34 and 76, which provide an electrical interconnection between bottomside interconnect layer 18 and top active surface 16, 16′ of die 14, 14′ and/or an electrical interconnection between bottomside interconnect layer 18 and topside interconnect layer 28 and/or an electrical interconnection between topside interconnect layer 28 and top active surface 16, 16′ of die 14′. Embedded electrical connections 180, 181 provide a similar type electrical interconnection between bottomside interconnect layer 152, interconnect layer 18, and top active surface 16″, 16′″ of die 14″, 14′″. Embedded electrical connections 210, 211 similarly provide electrical interconnection between bottomside interconnect layer 181, topside interconnect layer 184, and top active surface 16^{iv}, 16^{v} of die 14^{iv}, 14^{v}′.

The result is MCM module 10′″ includes a plurality of stacked die layers each having one or more die within a single multichip, two-sided substrateless multichip module.

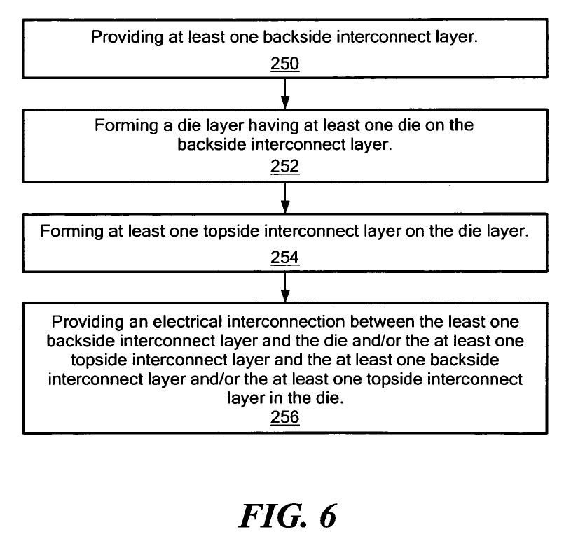

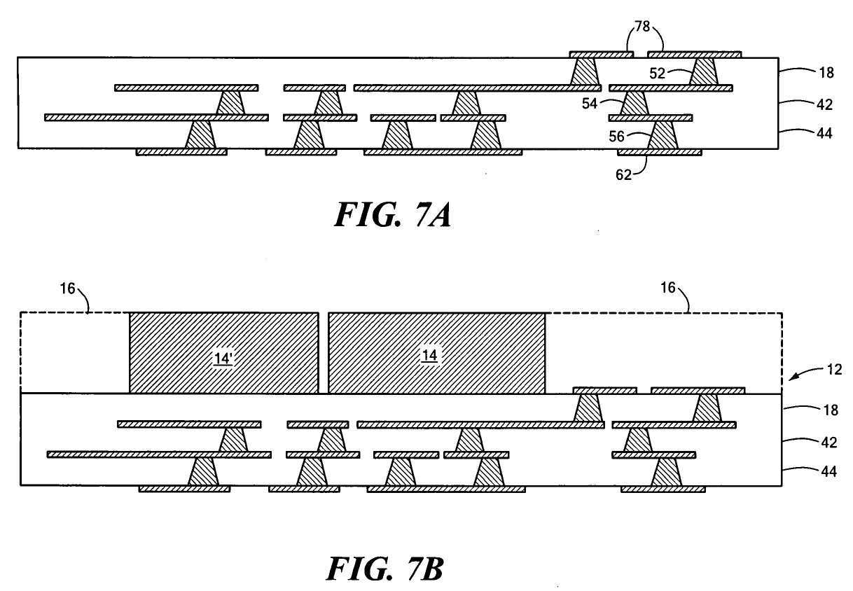

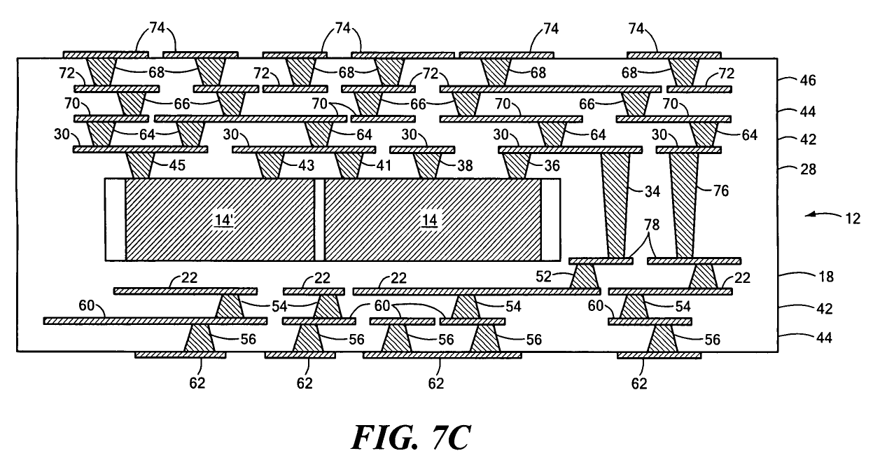

One example of the method of fabricating a two-side substrateless multichip module of this invention is discussed below with reference to FIGS. 3, 6 and 7A-7C. The method preferably includes the steps of: providing at least one bottomside interconnect layer, step 250, FIG. 6, e.g., bottomside interconnect layers 18, 42, and 44, FIG. 7A, of similar design as discussed above with reference to FIG. 3. A die layer having at least one die is formed on the bottomside interconnect layer, step 252, FIG. 6, e.g., die layer 12, FIG. 7B, including die 14 and die 14′. In one design, a spacer element is added to die layer 12, e.g., space element 16, FIG. 7B. At least one topside interconnect layer is formed on the die layer, step 254, FIG. 6, e.g., topside interconnect layers 28, 46, 48, and 50 formed over die layer 12, FIG. 7C. One or more electrical interconnection between the at least one bottomside interconnect layer and the die and/or the at least one topside interconnect layer and the at least one bottomside interconnect layer and/or the at least one topside interconnect layer and the die are provided, step 256, FIG. 6. For example, each of vias 52, 54, and 56 in bottomside interconnect layers 18, 42, and 44, respectively, are formed while each of bottomside interconnect layers 28, 42, and 44 are formed. Vias 36, 28, 41, 43, and 45 in topside interconnect layer 28 are similarly formed while topside interconnect layer 28 is formed over die layer 12. Vias 34 and 76 are then created between topside interconnect layer 28 and bottomside interconnect layer 18. Vias 64, 66, and 68 in topside interconnect layers 46, 48, and 50, respectively, are similarly formed during the creation of topside interconnect layers 46, 48, and 50, similar as discussed above with reference to FIG. 3. In this example, each of electrical contacts (pads, pattern material (metal traces)) 22, 60, and 62, FIG. 7C, in bottomside interconnect layer 18, 42 44, respectively, and electrical contacts 30, 70, 72 and 74 in topside interconnect layers 28, 46, 48, and 50, respectively, are formed while each of the bottomside and topside interconnect layers are formed, similar as discussed above with reference to FIG. 3.

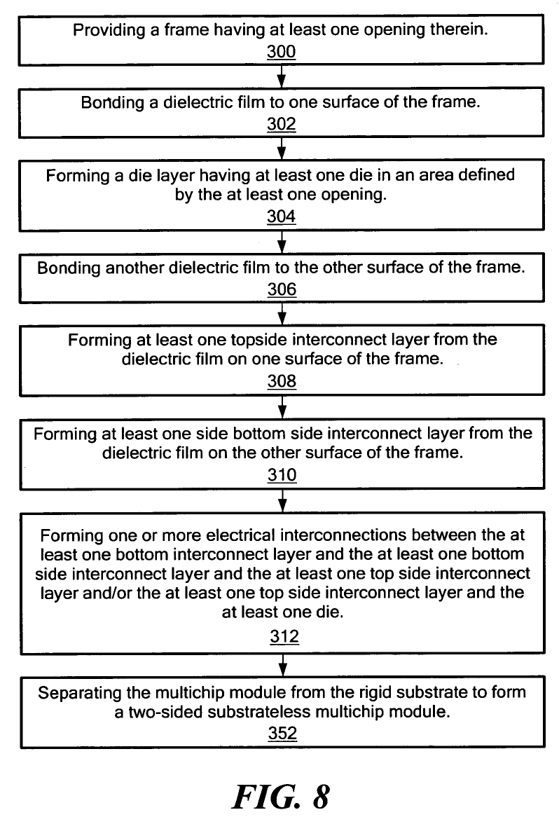

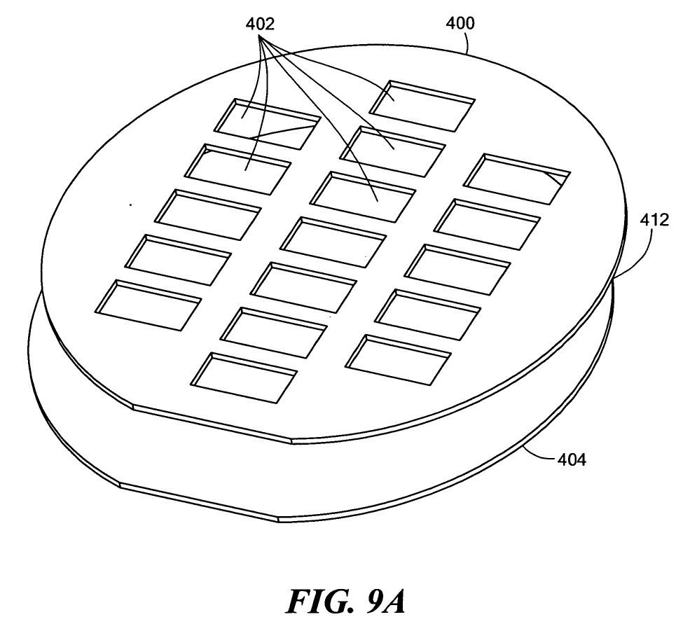

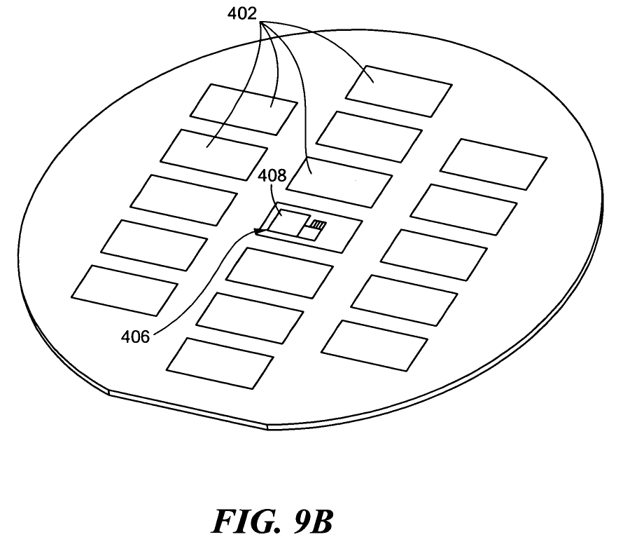

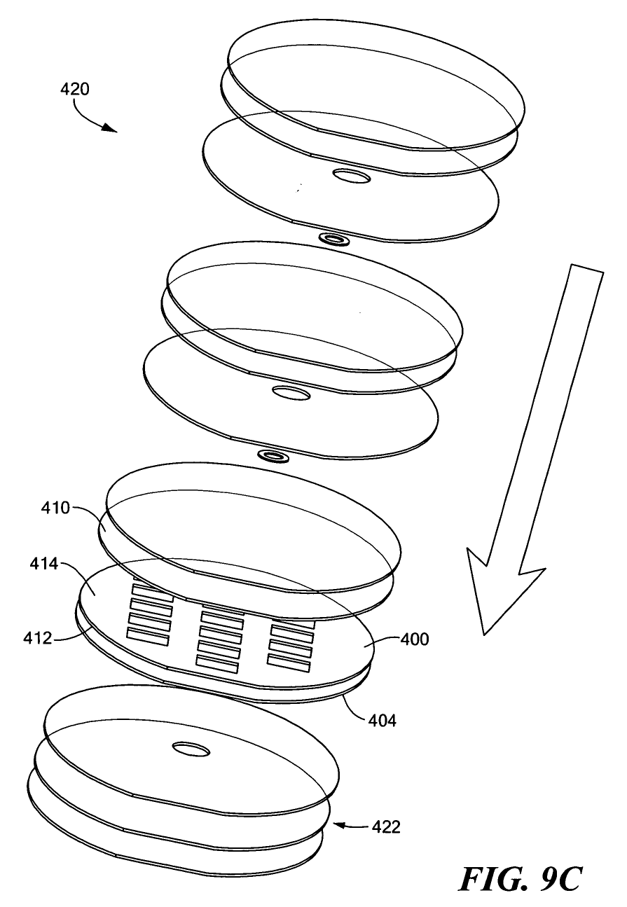

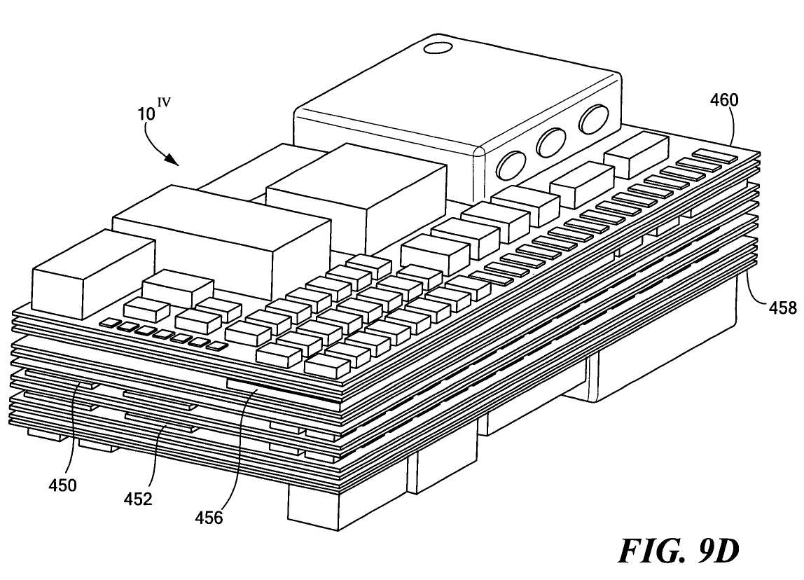

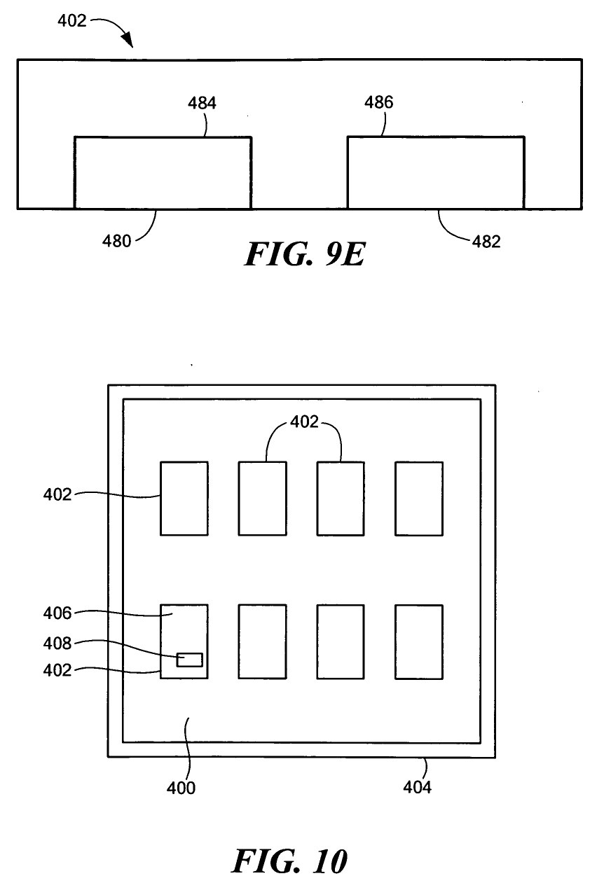

Another embodiment of the method of manufacturing a two-sided multichip module of this invention is described below with reference to FIGS. 8, 9A-9E, and 10. The method preferably includes the steps of providing a frame having at least one opening therein, step 300, FIG. 8, e.g., frame 400, FIG. 9A, with any and/or all of openings 402 therein. A dielectric film is then bonded to one surface of the frame, step 302, FIG. 8, e.g., dielectric film 404, FIG. 9A, made of polyimide, KAPTON®, or similar type material, bonded to bottom surface 412 of frame 400 with an adhesive. A die layer having at least one die is formed in the area defined by the at least one opening, step 304, FIG. 8, e.g., die layer 406, FIG. 9B, having at least one die 408 is formed in one of openings 402. FIG. 10, where like parts have been like numbers, shows in further detail one example of frame 400 in which one of openings 402 includes die layer 406 with die 408. Dielectric layer 404 is also shown attached to frame 400. Another dielectric film is bonded to the other surface of the frame, step 306, FIG. 8, e.g., dielectric film 410, FIG. 9C, is bonded to top surface 414 of frame 400 with an adhesive. At least one topside layer is formed from the dielectric film on one surface of the frame, step 308, FIG. 8, e.g., a topside interconnect layer discussed above in reference to any of FIGS. 1-7 is formed from dielectric film 410, FIG. 9C. At least one bottomside interconnect layer is formed on the other surface of frame, step 314, FIG. 8, e.g., a bottomside interconnect layer as discussed above in reference to any of FIGS. 1-5 and 7 is formed from dielectric film 404, FIG. 9C. Any number of various topside interconnect layers and die layers on the topside interconnect layers, indicated generally at 420, and bottomside interconnect layers and die layers on the bottomside interconnect layers, indicated generally at 422, are alternatively fabricated on opposites sides of frame 400 using standard processing techniques, such lamination, photolithography, and the like, as discussed above in reference to FIGS. 1-7. Stacking multiple topside and bottomside interconnect layers and die layers in this manner provides balance and symmetry for the two-sided substrateless MCM of this invention. Such a design allows the MCM to include up to eleven die layers, e.g., five die layers on each side of the frame, plus the initial die layer. In contrast, the die layer of conventional single-sided MCMs creates unbalanced stress, causing them to bow and malfunction.

The method may include separating the one or more multichips from the frame to form one or more multichip modules, step 352, FIG. 8, e.g., using a laser, as known by those skilled in the art. FIG. 9D shows one example of two-sided multichip module 10^{IV} manufactured in accordance with the method of this invention which includes three buried die levels 450, 452 and 456, as well as die layers 458 and 460 having a plurality of die thereon. Any of the dielectric films discussed above may include a flex circuit. Preferably the frame, e.g., 400, is thermally matched to dielectric film, e.g., dielectric film 404 and dielectric film 410. In one design, frame 400 is made of stainless steel, brass, silicone (preferably matched to the die), or a rigid polymer. Preferably, multiple layers are sandwiched between multiple interconnect layers, as discussed above.

In one design, a plurality of die in each of the die layers is preferably placed in openings in the frame such that the active surface of each of the die is co-planar, e.g., active surface 480, 482, FIG. 9E, of die 484 and 486, respectively, are placed co-planar in opening 402. Placing the plurality of die facedown and co-planar in opening 402, as shown, eliminates peaks and valleys on the surface of the interconnect layer and/or the die. This allows for the achievement of smaller interconnect geometry.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. A two-sided substrateless multichip module comprising:
at least one die layer having at least one die;
at least one bottomside interconnect layer coupled to a bottom surface of the at least one die;
at least one topside interconnect layer coupled to a top surface of the at least one die;
one or more embedded electrical connections configured to provide an electrical interconnection between the at least one bottomside interconnect layer and the at least one die and/or the at least bottomside interconnect layer and the at least one topside interconnect layer and/or the at least one topside interconnect layer and the at least one die; and
wherein the at least one bottomside interconnect layer includes one or more electrical contacts on a bottom surface of the multichip module and the at least topside interconnect layer includes one or more electrical contacts on a top surface of the multichip module.

2. The two-sided substrateless multichip module of claim 1 in which the at least one bottomside interconnect layer includes a flex circuit.

3. The two-sided substrateless multichip module of claim 1 in which the one or more of the electrical contacts on the bottom surface and/or the top surface have a predetermined pattern.

4. The two-sided substrateless multichip module of claim 3 in which the predetermined pattern is configured for attachment of one or more surface mount technology components.

5. The two-sided substrateless multichip module of claim 3 in which the one or more electrical contacts each provide an electrical connection to one or more of: solder balls and/or surface mount parts and/or external interconnect layers, flip chip die, and wire bonds.

6. The two-sided substrateless multichip module of claim 1 in which the at least one bottomside interconnect layer and the at least one topside interconnect layer each include a dielectric layer and one or more of metal traces, electrical contacts and vias.

7. The two-sided substrateless multichip module of claim 6 in which the dielectric layer includes an adhesive.

8. The two-sided substrateless multichip module of claim 6 in which the dielectric layer is comprised of polyimide.

9. The two-sided substrateless multichip module of claim 2 in which the flex circuit is configured for a predetermined die.

10. The two-sided substrateless multichip module of claim 1 in which the at least one bottomside interconnect layer is configured as a heat sink.

11. The two-sided substrateless multichip module of claim 1 in which the at least one topside interconnect layer is configured as a heat sink.

12. The two-sided substrateless multichip module of claim 1 in which the one or more electrical connections include one or more vias.

13. The two-sided substrateless multichip module of claim 1 in which the at least one die layer includes a dielectric spacer element.

14. The two-sided substrateless multichip module of claim 13 in which the dielectric spacer is comprised of polyimide.

15. The two-sided substrateless multichip module of claim 1 further including a plurality of bottomside interconnect layers.

16. The two-sided substrateless multichip module of claim 1 further including a plurality of topside interconnect layers.

17. The two-sided substrateless multichip module of claim 1 in which the at least one die layer includes a plurality of dies.

18. The two-sided substrateless multichip module of claim 1 further including a plurality of stacked die layers each sandwiched between at least one topside interconnect layer and at least one bottomside interconnect layer and having one or more electrical interconnections between the plurality of stacked die layers and/or between the at least one bottomside interconnect layer and the at least one die and/or the at least one topside interconnect layer and the bottomside interconnect layer and/or the at least one topside interconnect layer and the at least one die.

19. A two-sided substrateless single chip module comprising:
at least one die layer having at least one die;
at least one bottomside interconnect layer coupled to a bottom surface of the at least one die;
at least one topside interconnect layer coupled to a top surface of the at least one die;
one or more embedded electrical connections configured to provide an electrical interconnection between the at least one bottomside interconnect layer and the at least one die and/or the at least bottomside interconnect layer and the at least one topside interconnect layer and/or the at least one topside interconnect layer and the at least one die; and
wherein the at least one bottomside interconnect layer includes one or more electrical contacts on a bottom surface of the multichip module and the at least topside interconnect layer includes one or more electrical contacts on a top surface of the multichip module.

20. A method of fabricating a two-sided substrateless multichip module, the method comprising:
providing at least one bottomside interconnect layer;
forming a die layer having at least one die on the at least one bottomside interconnect layer;
forming at least one topside interconnect layer on the die layer; and
providing one or more electrical interconnections between the at least one bottomside interconnect layer and the at least one die and/or the at least one topside interconnect layer and the at least one bottomside interconnect layer and/or the at least one topside interconnect layer and the at least one die.

21. The method of claim 20 in which the at least one bottomside interconnect layer includes a flex circuit.

22. The method of claim 20 in which providing one or more electrical interconnections includes forming one or more vias between the at least one bottomside interconnect layer and the at least one die and/or the at least one topside interconnect layer and the at least one bottomside interconnect layer and/or the at least one topside interconnect layer in the at least one die.

23. The method of claim 20 further including the step of providing at least one spacer element to the die layer.

24. The method of claim 20 further including the step of providing one or more electrical contacts on a bottom surface of the two-sided substrateless multichip module.

25. The method of claim 20 further including the step of providing one or more electrical contacts on a top surface layer of the two-sided substrateless multichip module.

26. The method of claim 24 or 25 in which the one or more electrical contacts are formed in a predetermined pattern.

27. The method of claim 26 in which the predetermined pattern is configured for attachment of one or more surface mount technology components.

28. The method of claim 26 in which the predetermined pattern is configured for attachment of one or more of: solder balls and/or surface mount parts and/or external interconnect layers.

29. A method of fabricating a two-sided substrateless single chip module, the method comprising:
providing at least one bottomside interconnect layer;
forming a die layer having at least one die on the at least one bottomside interconnect layer;
forming at least one topside interconnect layer on the die layer; and
providing one or more electrical interconnections between the at least one bottomside interconnect layer and the at least one die and/or the at least one topside interconnect layer and the at least one bottomside interconnect layer and/or the at least one topside interconnect layer and the at least one die.

30. A method for fabricating one or more two-sided substrateless multichip modules, the method comprising:
providing a frame having at least one opening therein;
bonding a dielectric film to one surface of the frame;
forming a die layer having at least one die in an area defined by the at least one opening;
bonding another dielectric film to the other surface of the frame;
forming at least one topside interconnect layer from the dielectric film on the one surface of the frame;
forming at least one bottomside interconnect layer from the dielectric film on the other surface of the frame; and
forming one or more electrical interconnections between the at least one bottomside interconnect layer and the at least one die and/or the at least one bottomside interconnect layer and the at least one topside interconnect layer and/or the at least one topside interconnect layer and the at least one die.

31. The method of claim 30 further including the step of forming one or more die layers having at least one die therein on the at least one topside interconnect layer and/or the at least one bottomside interconnect layer.

32. The method of claim 30 in which the dielectric film includes a flex circuit.

33. The method of claim 30 in which the frame is thermally matched to the dielectric.

34. The method of claim 30 in which the frame is thermally matched to the at least one die.

35. The method of claim 30 in which the frame is made of a material chosen from the group consisting of: stainless steel, brass, silicone, and a rigid polymer.

36. The method of claim 31 in which the one or more die layers are each sandwiched between at least one topside interconnect layer and at least one bottomside interconnect layer.

37. The method of claim 30 further including a plurality of die in the die layer each placed in the opening such that the active surface of each of the die are co-planar.

38. A method for fabricating one or more two-sided substrateless single chip modules, the method comprising:
providing a frame having at least one opening therein;
bonding a dielectric film to one surface of the frame;
forming a die layer having at least one die in an area defined by the at least one opening;
bonding another dielectric film to the other surface of the frame;
forming at least one topside interconnect layer from the dielectric film on the one surface of the frame;
forming at least one bottomside interconnect layer from the dielectric film on the other surface of the frame; and
forming one or more electrical interconnections between the at least one bottomside interconnect layer and the at least one die and/or the at least one bottomside interconnect layer and the at least one topside interconnect layer and/or the at least one topside interconnect layer and the at least one die.
